(19) United States
(12) Patent Application Publication
(10) Pub. No.: US 2008/0013293 A1
(43) Pub. Date: Jan. 17, 2008

(54) Integrated circuit module

(75) Inventors: Yun-Chin Chen, Taoyuan Hsien (TW); Zheng-Ping Lan, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/812,476

(22) Filed: Jun. 19, 2007

(30) Foreign Application Priority Data
Jul. 17, 2006 (TW) 095126095

(51) Int. Cl. H05K 7/00

(52) U.S. Cl. 361/760

(57) ABSTRACT

An integrated circuit (IC) module includes a substrate, a first IC unit, a second IC unit, a cover and a carrier. The substrate has a first surface and a second surface opposite to the first surface. A plurality of first connecting pads is disposed on the second surface. The first IC unit is disposed on the first surface of the substrate. The cover covers the first IC unit. The second IC unit is disposed on the second surface of the substrate. The carrier is disposed corresponding to the first connecting pad and has a third surface, on which a plurality of second connecting pads is formed. The second connecting pads are electrically connected to the first connecting pads, respectively.

### CROSS REFERENCE TO RELATED APPLICATIONS

This Non-provisional application claims priority under 35 U.S.C. §119(a) on Patent Application No(s). 095126095 filed in Taiwan, Republic of China on Jul. 17, 2006, the entire contents of which are hereby incorporated by reference.

### BACKGROUND OF THE INVENTION

1. Field of Invention

The invention relates to an integrated circuit (IC) module, and in particular, to an IC module of a multi-chip module (MCM) and a multi-package module (MPM).

2. Related Art

With the progress of the semiconductor technology, the application range of the integrated circuit is expanding, and almost all electronic products have integrated circuits. In addition, the development of IC package technology is following a trend toward greater miniaturization and compactness to accommodate the increasingly miniaturized and light-weighted design of electronic products. The high density IC package technology of forming, for example, a ball grid array (BGA) module, a chip-scale package (CSP), a multi-chip module (MCM) or a multi-package module (MPM), has been introduced and developed, and the duplex IC package has been developed recently.

Referring to FIG. 1, a conventional IC module 1 with a duplex package has a substrate 11, ICs (the so-called chips) 12 and 13 respectively disposed on an upper surface 111 and a lower surface 112 of the substrate 11, and a plurality of bonding pads 113 (see FIG. 2) formed on the lower surface 112 around the IC 13. The bonding pads 113 of the ICs 12 and 13 serve as output/input ports for the signal transmission between the ICs 12 and 13 and other devices.

Referring to FIG. 3, when the IC module 1 is to be placed on a printed circuit board 2, bonding pads 21 corresponding to the bonding pads 113 have to be formed on a surface of the printed circuit board 2. Then, solder balls 15 are utilized to bond the bonding pads 113 to the bonding pads 21, respectively, and then reflowed to electrically connect the IC module 1 to the printed circuit board 2. The height of the solder ball 15 has to be greater than that of the IC 13 in order to prevent the IC 13 from influencing the electrical connections between the bonding pads.

However, the present IC module is small but has a great number of pins (a number of bonding pads), such that the distance between the bonding pads is very small. Once the IC module 1 has to be disassembled, it will require a lot of time and personnel costs. In general, the IC module 1 is slowly removed after the solder balls 15 are melted by using a hot air steam or a heat platen. Because the number of the bonding pads 113 of the IC module 1 is very great, it is difficult to remove the bonding pads 113 simultaneously. In addition, after the IC module 1 is removed, the solder ball 15 deforms to form the solder ball 15′ of FIG. 4 and cannot be used when the IC module 1 is repaired. In addition, it is necessary to consider the heat withstanding extent of the IC 13 around the bonding pads 113 on the lower surface 112. When the IC module 1 is disassembled or repaired, excessive temperature tends to damage the IC 13. Thus, when the IC module 1 is disassembled and repaired, the time and the personnel cost are increased and the yield and reliability of the IC module diminished.

In view of this, it is an important subject to provide an IC module, which has a duplex package and can be disassembled and repaired more easily so that the reliability of the repaired IC package can be increased.

### SUMMARY OF THE INVENTION

To achieve the above, an IC module according to the invention includes a substrate, a first IC unit, a cover, a second IC unit and a carrier.

The substrate has a first surface and a second surface opposite to the first surface. A plurality of first connecting pads is formed on the second surface. The first IC unit is disposed on the first surface of the substrate. The cover covers the first IC unit. The second IC unit is disposed on the second surface of the substrate. The carrier is disposed corresponding to the first connecting pads and has a third surface. A plurality of second connecting pads respectively electrically connected to the first connecting pads is formed on the third surface.

As mentioned above, the IC module according to the invention has the additional carrier, and the first connecting pads are electrically connected to the second connecting pads of the carrier. When the IC module is disposed on a printed circuit board and needs to be disassembled or repaired, the carrier is separated from the printed circuit board. Compared with the prior art IC module, the second IC unit cannot be easily touched and thereby damaged. Therefore, the IC module may have enhanced yield and reliability after the IC module is disassembled or repaired.

### BRIEF DESCRIPTION OF THE DRAWINGS

The invention will become more fully understood from the detailed description given herein below illustration only, and thus is not limitative of the present invention, and wherein:

FIGS. 1 to 3 are schematic illustrations showing a conventional IC module;

FIG. 4 is a schematic illustration showing solder balls deformed when the conventional IC module is disassembled;

FIG. 5 is a schematic illustration showing an IC module according to an embodiment of the invention;

FIGS. 6 and 7 are schematic illustrations showing a carrier of the IC module according to the embodiment of the invention; and

FIG. 8 is a schematic illustration showing another IC module according to the embodiment of the invention;

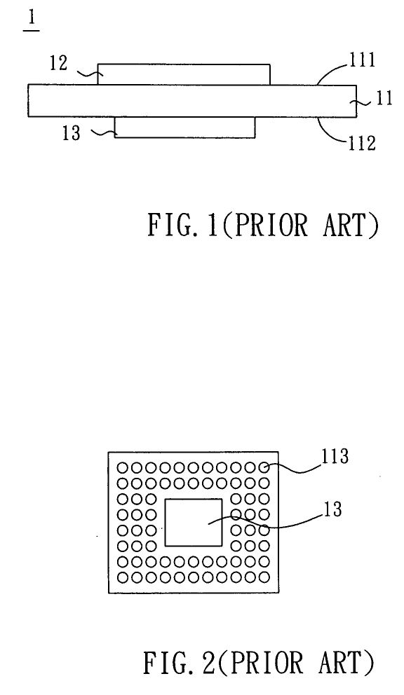

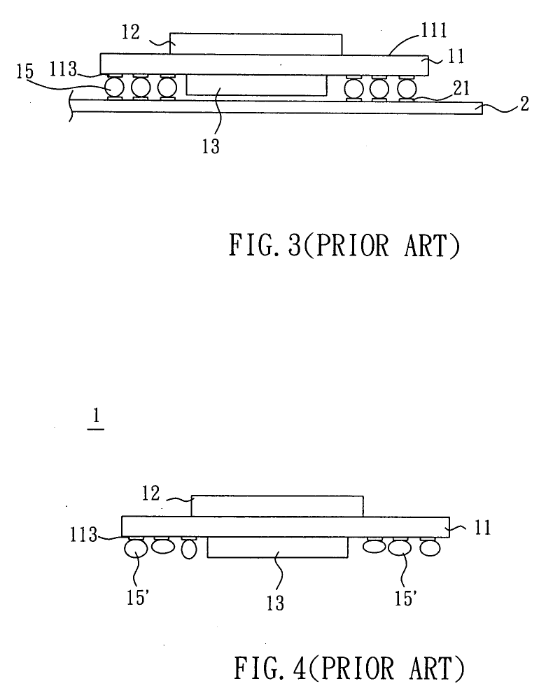

### DETAILED DESCRIPTION OF THE INVENTION

The present invention will be apparent from the following detailed description, which proceeds with reference to the accompanying drawings, wherein the same references relate to the same elements.

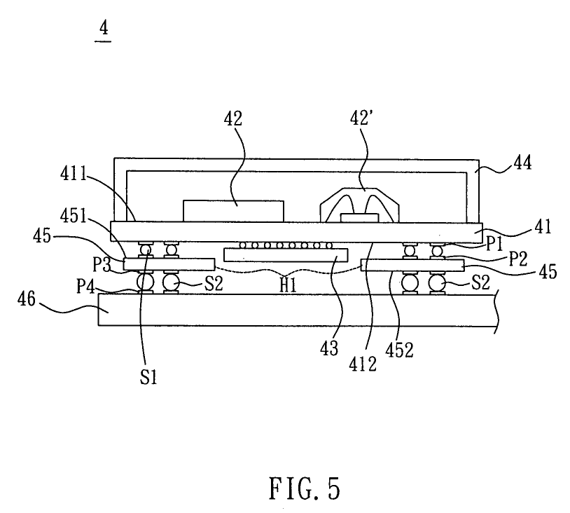

Referring to FIG. 5, an IC module 4 according to the embodiment of the invention includes a substrate 41, a first IC unit 42, a second IC unit 43, a cover 44, a carrier 45 and a printed circuit board 46. Each of the first IC unit 42 and the second IC unit 43 may be a chip or a package.

The substrate 41 has a first surface 411 and a second surface 412 disposed opposite to the first surface 411, and a plurality of first connecting pads P1 is formed on the second surface 412. In this embodiment, the substrate 41 can be a dual-layer circuit substrate or a multi-layer circuit substrate according to the actual requirement, and can be made of glass, bismaleimide-triazine (BT) resin, fiberglass reinforced epoxy resin (FR4) or Getek resin.

The first IC unit 42 is disposed on the first surface 411 of the substrate 41. In this embodiment, the first IC unit 42 can be disposed on the first surface 411 of the substrate 41 by the surface mount technology (SMT), wire bonding technology or flip-chip bonding technology according to the actual conditions.

The cover 44 covers the first IC unit 42 to protect the first IC unit 42 from collision and damage. In this embodiment, the cover 44 may be made of resin or metal.

The second IC unit 43 is disposed on the second surface 412 of the substrate 41, and is disposed on the second surface 412 of the substrate by the surface mount technology or the flip-chip bonding technology.

The carrier 45 can be a dual-layer circuit board or a multi-layer circuit board, which is disposed corresponding to the first connecting pads P1 of the substrate 41. The carrier 45 has a third surface 451 and a fourth surface 452 opposite to the third surface 451. A plurality of second connecting pads P2 is formed on the third surface 451, and a plurality of third connecting pads P3 is formed on the fourth surface 452. In this embodiment, the second connecting pad P2 is electrically connected to the first connecting pad P1 through a solder ball S1, and can be electrically connected to the first connecting pad P1 through a conductive bump or a conductive adhesive. The third connecting pad P3 is electrically connected to the second connecting pad P2 through a metal wire or a via. In addition, the thickness of the carrier 45 is greater than that of the second IC unit 43 in order to prevent the second IC unit 43 from influencing the electrical connection between the first connecting pad P1 and the second connecting pad P2. Of course, it is also possible to prevent the second IC unit 43 from influencing the electrical connection between the first connecting pad P1 and the second connecting pad P2 by controlling the height of the solder ball S1 or the conductive bump.

In this embodiment, the first connecting pad P1 of the substrate 41 is electrically connected to the second connecting pad P2 of the carrier 45 by the surface mount technology, and then a non-conductive adhesive is applied between the substrate 41 and the carrier 45 so as to enhance the structural stability.

Furthermore, the carrier 45 of this embodiment is a dual-layer circuit substrate and is made of, without limitation, glass, bismaleimide-triazine (BT) resin, fiberglass reinforced epoxy resin (FR4) or Getek resin. In this example, the carrier 45 is made of the cheaper FR4.

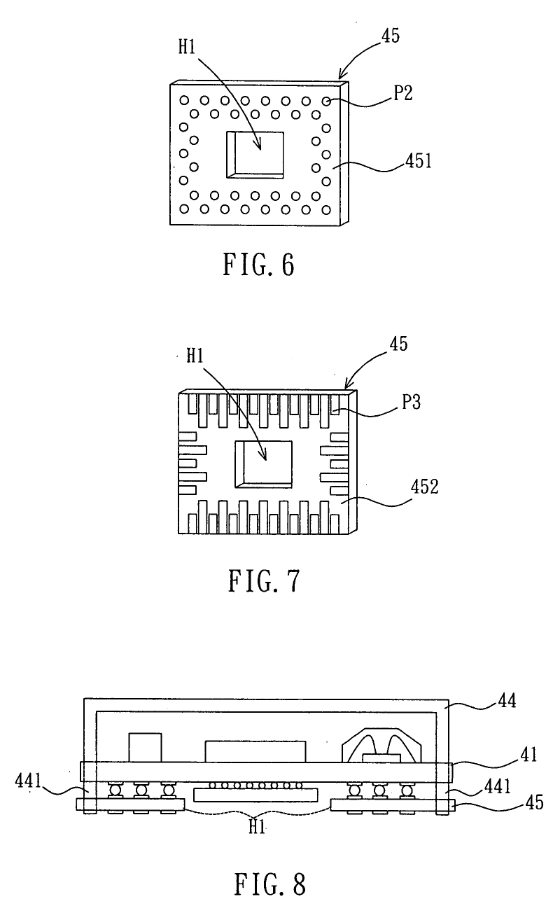

Referring to FIG. 6, the carrier 45 has a hollow portion H1, which is disposed corresponding to the second IC unit 43. That is, the second IC unit 43 can be partially accommodated in the hollow portion H1 so that the overall thickness of the IC module may be reduced.

In addition, the second connecting pads P2 formed on the third surface 451 of the carrier 45 can be arranged as a ball grid array (BGA), as shown in FIG. 6, and the third connecting pads P3 formed on the fourth surface 452 of the carrier 45 can be arranged as a lane grid array (LGA), as shown in FIG. 7. In other words, the first connecting pads P1 corresponding to the second connecting pads P2 can also be arranged as the ball grid array.

As shown in FIG. 8, the cover 44 has a fixing portion 441, which passes through the substrate 41 and is connected to the carrier 45, for stabilizing the connection between the substrate 41 and the carrier 45. In this embodiment, the fixing portion 441 is made of metal, for example, and is fixed onto the carrier 45 by bonding. In addition, the fixing portion 441 can also be fixed onto the carrier 45 by adhering or screwing.

As shown in FIG. 5, the printed circuit board 46 has a plurality of fourth connecting pads P4 respectively electrically connected to the third connecting pads P3 of the carrier 45. In this embodiment, the third connecting pads P3 may also be the lane grid array and may also be electrically connected to the fourth connecting pads P4 by the surface mount technology or the flip-chip bonding technology. In addition, the third connecting pad P3 may be electrically connected to the fourth connecting pad P4 through the solder S2, a solder ball, a conductive bump or a conductive adhesive.

In this embodiment, the third connecting pad P3 of the carrier 45 may also be electrically connected to the fourth connecting pad P4 of the printed circuit board 46 by the surface mount technology. Similar to the above-mentioned example, the non-conductive adhesive is then applied between the carrier 45 and the printed circuit board 46 in order to enhance the structural stability.

In the embodiment as shown in FIG. 5, the first IC unit can be a light-emitting diode 42′ disposed on the first surface 411 and the cover 44 can be made of transparent material.

In summary, the IC module according to the invention has the additional carrier, and the first connecting pads are electrically connected to the second connecting pads of the carrier. When the IC module is disposed on a printed circuit board and needs to be disassembled or repaired, the carrier is separated from the printed circuit board. Compared with the prior art IC module, the second IC unit cannot be easily touched and thereby damaged. In addition, if the carrier is bonded to the printed circuit board through the lane grid array, the IC module may be disassembled and repaired more easily as compared with the IC module having the carrier bonded to the printed circuit board through the ball grid array and has enhanced yield and reliability after the IC module is disassembled or repaired.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An integrated circuit (IC) module comprising:
a substrate having a first surface and a second surface opposite to the first surface, wherein the second surface has at least one first connecting pad;
a first IC unit disposed on the first surface of the substrate;
a second IC unit disposed on the second surface of the substrate; and
a carrier disposed corresponding to the first connecting pad, wherein the carrier has a third surface, and at least one second connecting pad electrically connected to the first connecting pad is formed on the third surface.

2. The IC module according to claim 1, further comprising a non-conductive adhesive applied between the substrate and the carrier to enhance structural stability of the IC module.

3. The IC module according to claim 1, wherein the carrier further has a fourth surface opposite to the third surface, and at least one third connecting pad electrically connected to the second connecting pad is formed on the fourth surface.

4. The IC module according to claim 3, wherein the second connecting pad is electrically connected to the third connecting pad through a metal wire or a via.

5. The IC module according to claim 3, further comprising a printed circuit board having at least one fourth connecting pad electrically connected to the third connecting pad of the carrier.

6. The IC module according to claim 5, further comprising a non-conductive adhesive applied between the carrier and the printed circuit board to enhance structural stability of the IC module.

7. The IC module according to claim 5, wherein the third connecting pad is electrically connected to the fourth connecting pad through a solder, a solder ball, a conductive bump or a conductive adhesive.

8. The IC module according to claim 1, wherein the substrate and the carrier are dual-layer circuit substrates or multi-layer circuit substrates.

9. The IC module according to claim 1, wherein the substrate and the carrier are made of glass, bismaleimide-triazine resin, glass fiber epoxy resin or Getek resin.

10. The IC module according to claim 1, wherein the first connecting pad is electrically connected to the second connecting pad through a conductive adhesive, a solder ball or a conductive bump.

11. The IC module according to claim 1, further comprising a cover covering the first IC unit.

12. The IC module according to claim 11, wherein the cover is made of resin or metal.

13. The IC module according to claim 11, wherein the cover has a fixing portion passing through the substrate.

14. The IC module according to claim 13, wherein the fixing portion is connected to the carrier.

15. The IC module according to claim 13, wherein the fixing portion is fixed onto the carrier by bonding, adhering or screwing.

16. The IC module according to claim 1, wherein the carrier has a hollow portion disposed corresponding to the second IC unit.

17. The IC module according to claim 1, wherein a thickness of the carrier is greater than or equal to that of the second IC unit.

18. The IC module according to claim 1, wherein the first and second connecting pads are arranged as a ball grid array or a lane grid array.

19. The IC module according to claim 1, wherein the first IC unit and the second IC unit are a chip or a package.

20. The IC module according to claim 1, wherein the first IC unit is disposed on the first surface of the substrate by surface mount technology (SMT), wire bonding technology or flip-chip bonding technology, and the second IC unit is disposed on the second surface of the substrate by surface mounting technology or flip-chip bonding technology.
